(19) United States
(12) Patent Application Publication
(10) Pub. No.: US 2003/0035450 A1
(43) Pub. Date: Feb. 20, 2003

(54) Optoelectronic packaging design to minimize optical subassembly tilt error

(75) Inventors: Jing-Hua He, Macungie, PA (US); John J. Kilgarriff, King of Prussia, PA (US); Erming Luo, Orefield, PA (US); John Osenbach, Kutztown, PA (US); Brian D. Potteiger, Reading, PA (US); Harry Reichelderfer, Macungie, PA (US); Rao Yelamarty, Allentown, PA (US)

Correspondence Address: Ms. Kyshon Rivers, Agere Systems Inc, c/o Lucent Technologies, 600 Mountain Avenue, Room 3A 506, Murray Hill, NJ, 07974-0636, US

(73) Assignee: Agere Systems Inc.

(21) Appl. No.: 09/932,890

(22) Filed: Aug. 20, 2001

(51) Int. Cl. H01S 5/22

(52) U.S. Cl. 372/36

(57) ABSTRACT

A structure for holding an optical subassembly such as a laser and which minimizes the tilt of the optical subassembly. Pads are placed between the optical subassembly and the housing forming grooves along the inside of the housing and between the pads. The solder for mounting the subassembly to the housing is placed in the grooves. The volume of the solder is chosen so that it does not overflow the grooves. But the solder can be constructed so that its height is greater than the height of the grooves. The optical subassembly is placed against the solder with a downward force and heat is applied to the bottom of the base to melt the solder.

### BACKGROUND OF THE INVENTION

1. Field of the Invention

The present invention relates to optoelectronic packaging design and an optical subassembly designed to minimize optical subassembly tilt error and to provide height control of an optical subassembly, including fluxless soldering of optical components.

2. DESCRIPTION OF THE PRIOR ART

One of the goals of laser power distribution is to improve the laser power distribution of the laser emitter package by making the spread (σ) of laser power distribution as narrow as possible. Many factors affect the laser power distribution of a laser emitter package. One of the factors is the tilt of the optical subassembly (OSA). Excessive tilt contributes to extreme lower power distribution. Previous attempts to correct the problem and improve the laser power distribution involved improvement of the die-bond machine's accuracy by placing the OSA into a laser sled housing to avoid the OSA's excessive planar rotational error. However, during the die-bond machine test, excessive rotational placement error contributed to extreme lower power distribution. Therefore, it has been observed that improving the die-bond machine's accuracy will only partially improve laser power distribution and will not be able to eliminate the problem totally.

One factor contributing to the OSA's tilt has been identified as the OSA's tilt due to the solder forming an unevenly distributed layer between the OSA and the laser sled housing. The current problem is illustrated in FIGS. 1 and 2 which show the prior art designs. FIG. 1 shows a prior art laser sled housing 10 for an OSA. A current OSA block 12 has a flat bottom 14. When the OSA block 12 is assembled into a laser sled housing 10, it seats on a thin layer of solder material such as solder paste, a solder preform, a reflowed solder preform, or pre-deposited solder. As will be known to those skilled in the art, the configuration shown in FIG. 1 is also used to assemble a current OSA into a detector sled housing. Although the layer of solder material 16 is usually 25 μm thick, it is still very difficult to control the orientation of the OSA 12 using the prior art configuration shown in FIG. 1.

FIG. 2 illustrates the problem that develops with the prior art configuration, with like numbers being used to designate like elements. FIG. 2 shows the current problem when the OSA 12 is placed into the laser sled housing 10 by seating it on solder material 16. The OSA 12 will seat on the solder material 16 without good orientation because it can pitch, roll, or tilt easily. When the prior art OSA design with OSA seating on top of the solder material is used, the OSA tends to tilt, roll, and pitch. These problems are very difficult to control in the manufacturing process.

Another attempt to control the problem used a new canal feature in laser sled housing design. However, the canal feature design requires more careful design of the laser sled housing resulting in many dimension and stability issues.

Therefore, there is a need to improve the laser power distribution by improving the OSA's tilt, pitch, and roll error and to provide accurate orientation for an OSA in three dimensional space and to make the manufacturing process easier.

### SUMMARY OF THE INVENTION

An advantage of the present invention is that it improves laser power distribution of a laser emitter package. The present invention is directed to unique structure designs of the laser sled housing which stops solder material from forming an uneven distribution layer between the OSA and the laser sled housing package which, in turn, improves the OSA tilt problem. The housing design is aided by the use of a new fluxless soldering technique.

### BRIEF DESCRIPTION OF THE DRAWINGS

FIG. 1 is side view of a prior art design for placing an OSA block on top of solder material inside a laser sled housing.

FIG. 2 is a side view of the same prior art design in FIG. 1 and showing how the solder material causes tilting of the OSA block.

FIG. 3 is a side view of an embodiment of the invention for placing an OSA on top of pads inside a laser sled housing.

FIG. 4 is a perspective view of the embodiment of the invention shown in FIG. 3.

FIG. 5 is a side view of a second embodiment of the invention using a different placement of pads.

FIG. 6 is a perspective view of the second embodiment of the invention using a different place of pads.

FIG. 7 is a perspective view of a third embodiment of the invention showing the use of a single cavity for placement of solder.

FIG. 8 is a side view of the third embodiment of the invention showing the direction of force and the direction of heat.

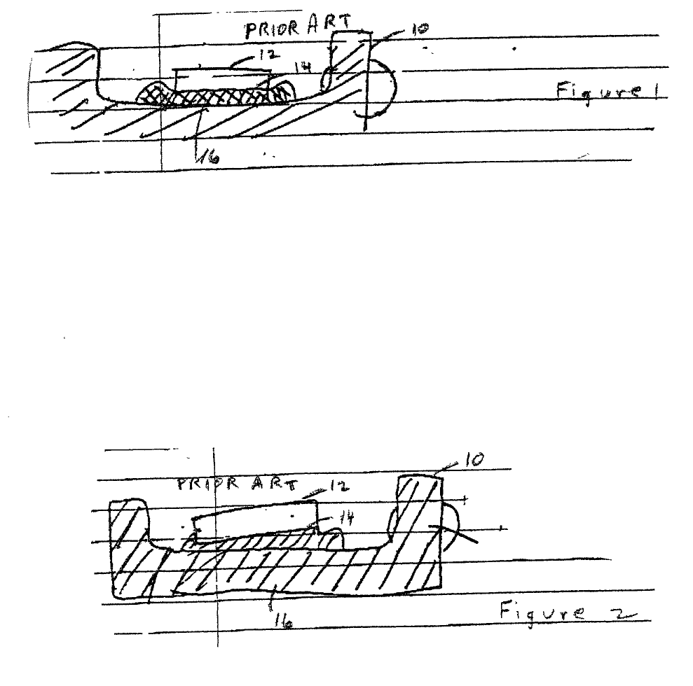

### DETAILED DESCRIPTION OF THE INVENTION

The invention will be understood more fully from the detailed description given below and from the accompanying drawings of embodiments of the invention which, however, should not be taken to limit the invention to a specific embodiment, but is for explanation and understanding only.

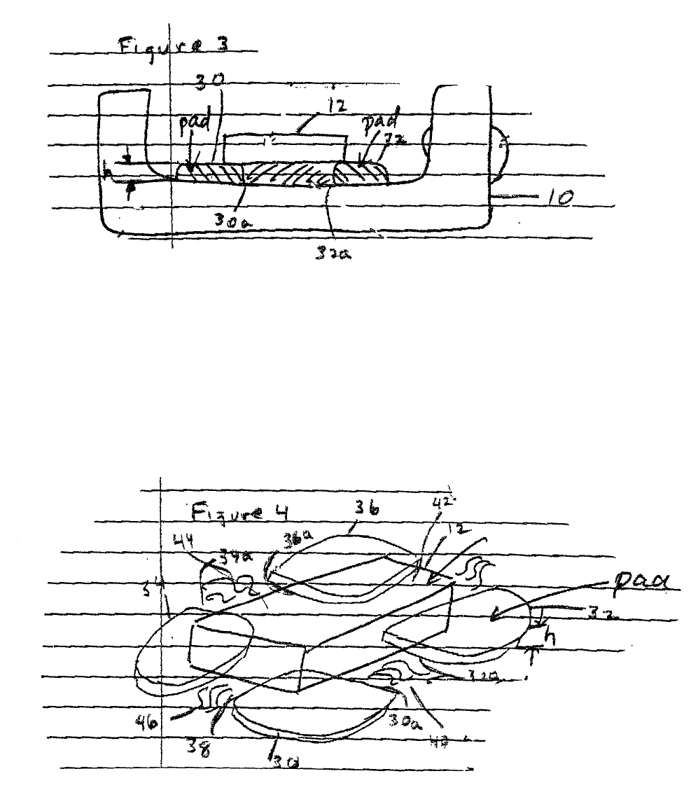

FIGS. 3 and 4 show an embodiment of the invention which is a new structure design of the laser sled housing which stops the solder material from forming an uneven distribution layer between the OSA and the laser sled housing package. This embodiment improves the OSA tilt problem. Again, the same numbers will identify like elements of the embodiment.

FIG. 3 shows an OSA block inside a laser sled housing 10. In an embodiment of the invention, the OSA block 12 rests on a series of pads 30, 32 which, in turn, rest on the inside of the laser sled housing 10. The relationship between the pads 30, 32 and the OSA block is shown more clearly in FIG. 4. FIG. 4 shows that the OSA block 12 rests on four pads 30, 32, 34, and 36, one pad for each corner of the OSA block 10. The bottom of pads 30, 32, 34, 36 rest on the inside of laser sled housing 10. Each of the pads 30, 32, 34, 36 has a thickness h which raises the OSA block 10 above the inside of the laser sled housing 10 by a distance equal to the thickness h of the pads. The pads 30, 32, 34, 36 may be constructed of plastic, metal, or other materials with similar characteristics.

The four pads 30, 32, 34, 36 have sides 30a, 32a, 34a, 36a. The pads are designed to be small enough so that none of the sides touch each other. Instead, the sides of the pads form groove-like spaces 38, 40, 42, 44 between them. The grooves form channels for melted solder material 46 to be placed between the sides in order to fix the OSA block 12 to the laser sled housing 10. The solder material volume is controlled so that it does not greatly exceed the volume of each groove. The shape of the pads can vary as long as they provide support for the four corners of the OSA and allow for grooves between their sides. Thus, the pads will touch the laser sled housing base and thus provide geometry support for the OSA instead of letting the OSA be seated on the solder material. It will be understood by those skilled in the art that these embodiments of the invention, as well as all other embodiments of the invention, will work equally well when epoxy is substituted for solder material or when various combinations of solder material and epoxy are used or any materials that are equivalent to solder material or epoxy are used.

The embodiment of the invention shown in FIGS. 3 and 4 support the OSA in three dimensional space instead of allowing the OSA to float on the solder material without solid support. Thus, this embodiment of the invention eliminates possible tilt, roll, and pitch of the OSA inside the laser sled. This embodiment makes the OSA's orientation inside the laser sled accurately located. Thus, the pads in this embodiment, and in all embodiments, also provide the ability to control the vertical position of the OSA.

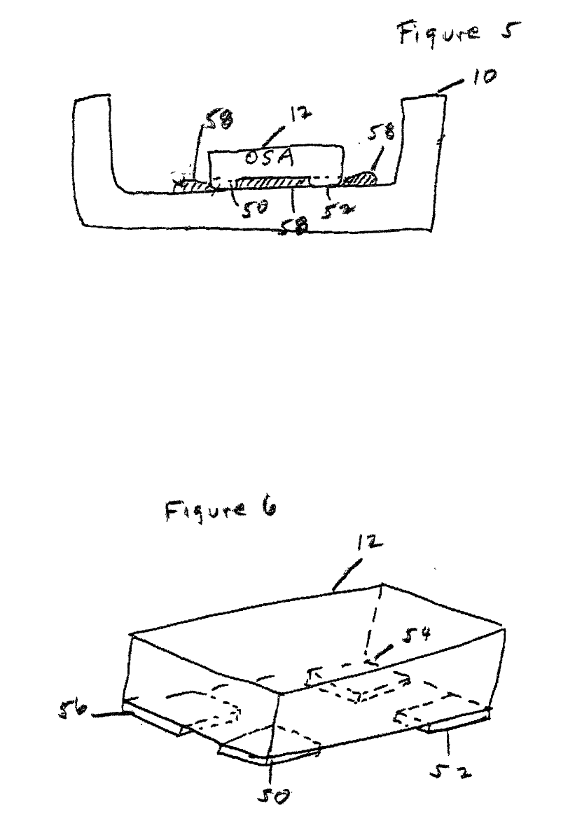

Another embodiment of the invention is shown in FIGS. 5 and 6 where foot pads 50, 52, 54, 56 are attached directly to the bottom of OSA 12 and are part of the OSA. In this embodiment, the OSA 12 rests directly on the inside of sled housing 10 through the foot pads 50, 52, 54, 56. The sides of the foot pads form grooves for receiving the solder material. In this embodiment, the OSA will be pushed down into the sled housing 10 until the OSA's pads contact the inside base of the housing. The solder material 58 will then flow under the OSA between the foot pads. The free flowing solder will form a good solder joint between the OSA 12 and the housing 10. Furthermore, using this embodiment will not require monitoring of the thickness of the solder material. The foot pads provide good geometry restraint thereby eliminating the OSA tilt problem.

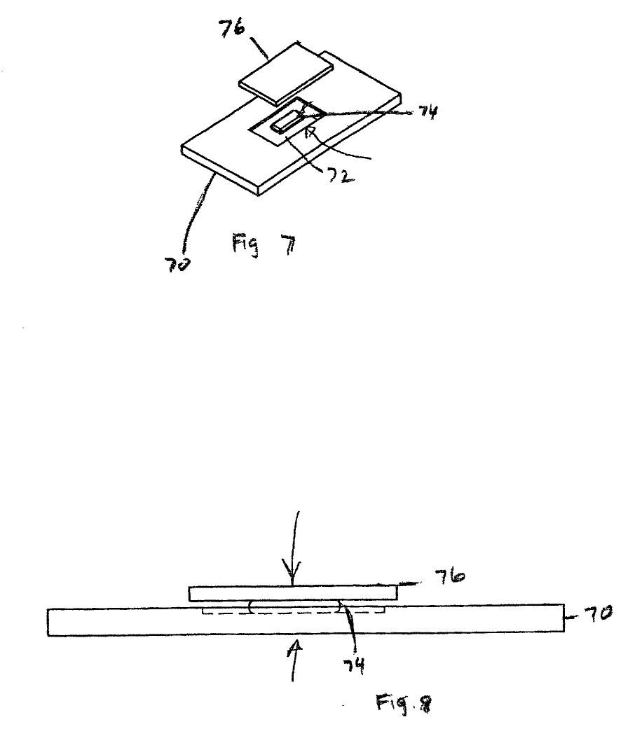

Another embodiment of the invention is shown in FIGS. 7 and 8. In this embodiment, a component may be soldered to the base using a cavity and fluxless solder. More specifically, base 70 has a cavity 72. A pre-measured block of solder 74 is placed inside cavity 72. The volume of solder 74 is designed so that it is smaller than the perimeter of the cavity 74, but higher than the walls of the cavity. The bottom surface of cavity 72 and the bottom of component 76 are plated with gold.

As shown in FIG. 8, after the solder 74 is placed in the cavity, the component, such as an OSA, is placed on top of the solder with a downward force against the solder. The downward force is sufficiently large so that it breaks the oxidation layer in the surface of the solder. Heat is applied to the bottom of the base to melt the solder. The temperature of the heat applied to the base 70 is higher than the melting point of the solder thereby causing the solder to liquefy. The volume of the solder is such that it just fills the cavity without overflowing the cavity.

When the solder is heated, the preform collapses emitting solder from one or more edges. The solder flows in the cavity which is now contained on top by the component 76, forcing the solder to fill the cavity 72 and make wet contact with both Au surfaces. The solder is forced to flow inside the cavity and wet the surfaces creating a solder joint without compromising physical alignment of the component 76 with the base 70.

The design and method described in connection with FIGS. 7 and 8 can be used either with a single cavity or groove as shown in those figures or can be used in connection with the pads and grooves shown in FIGS. 3, 4, 5, and 6.

The designs disclosed herein are not limited to a detector OSA or to an emitter (laser) OSA. It applies to any OSA design for all general optical packaging and to any other components which must be soldered together.

While the invention has been described with specificity, additional advantages and modifications will readily occur to those skilled in the art. Therefore, the invention in its broader aspects is not limited to the specific details shown and described herein. Accordingly, various modifications may be made without departing from the spirit or scope of the general inventive concepts as defined by the appended claims and their equivalents.

We claim:

1. A support device for an optical subassembly, providing control of the orientation of said optical subassembly, comprising:
a housing having an inside for supporting said optical subassembly;
one or more pads mounted on the inside of said housing;
the inside of said housing being adapted to support the underside of said pads;
the topside of said pads being adapted to support said subassembly.

2. The support device of claim 1 wherein said pads control the vertical position of the subassembly.

3. The support device of claim 1 wherein said pads are spaced around the inside of said housing so as to provide support for the corners of the subassembly.

4. The support device of claim 1 wherein the spaces between said pads form grooves along the inside of said housing.

5. The support device of claim 4 wherein said grooves are adapted to receive solder material, or epoxy, or a combination of solder material and epoxy.

6. The support device of claim 5 wherein the volume of solder material, or epoxy, or combined solder material and epoxy does not exceed the volume of the grooves formed by said pads.

7. A device for improving the laser power distribution of a laser emitter package comprising:
an optical subassembly;
a housing having an inside for supporting said optical subassembly;
said optical subassembly having footpads attached to a bottom thereof;
said optical subassembly and said footpads being adapted to fit inside said housing and to rest on an inside floor of said housing;
the footpads being at spaced separation from one another and the spaces between the said footpads being adapted to receive solder.

8. The device of claim 7 wherein said footpads raise said optical assembly above the inside floor of said housing.

9. The device of claim 7 wherein said footpads control the vertical position of the optical assembly.

10. The device of claim 8 wherein the spaces between said footpads form grooves along the inside floor of said housing.

11. The device of claim 10 wherein the grooves are adapted to receive solder material.

12. The device of claim 11 wherein the volume of said solder material does not exceed the volume of the grooves formed by said footpads.

13. A method for minimizing optical subassembly tilt error including:
forming at least one groove in a housing for the subassembly;
predetermining a volume of solder to be placed into the groove by
making the solder into a block form;
making a volume of the block equal to a volume of the groove;
making a vertical height of the block higher than a vertical height of the groove;
placing the predetermined volume of solder into said groove;
placing said subassembly on top of the block of solder with a downward force against the solder; and
applying heat to a bottom of the housing to liquefy the solder.

14. The method of claim 13 wherein the downward force applied to the solder is sufficiently large to break the oxidation layer in the surface of the solder.

15. The method of claim 13 wherein the heat applied the bottom of the housing is higher than the melting point of the solder.

16. The method of claim 13 wherein the surface of the groove and the bottom of the subassembly are plated with gold.
